(19) United States
(12) Patent Application Publication
(10) Pub. No.: US 2026/0343841 A1
(43) Pub. Date: Oct. 29, 2026

(54) ACTIVE SYCHRONIZED VIBRATION DAMPING OF PLACEMENT HEAD

(71) Applicant: Koenraad Alexander GIESKES

(72) Inventor: Koenraad Alexander GIESKES

(21) Appl. No.: 19/124,379

(22) PCT Filed: Oct. 27, 2023
(86) PCT No.: PCT/US2023/036083

§ 371 Date: Apr. 25, 2025

(51) Int. Cl. H05K 13/04

(52) U.S. Cl. CPC H05K 13/0406

(57) ABSTRACT

An electronic device placement system includes a placement head including a spindle, a positioning system configured to move the spindle between a picking location and a placement location, a spindle assembly Z-drive, a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller and a spindle accelerometer system connected to the motion controller. The electronic device placement system includes a substrate support configured to hold a substrate that is a target for placement of an electronic component by the spindle and a substrate accelerometer system mounted to the substrate support, the substrate accelerometer system configured to measure vibrations in the X-direction and the Y-direction.

### RELATED MATTERS

This application is a national stage of PCT Application No. PCT/US2023/036083, having a filing date of Oct. 27, 2023, which claims priority to U.S. Provisional Patent Application 63/419,815, having a filing date of Oct. 27, 2022, and entitled “ACTIVE SYCHRONIZED VIBRATION DAMPING OF PLACEMENT HEAD” the disclosure of which is hereby incorporated by reference.

### TECHNICAL FIELD

This invention relates generally to placement of electronic devices, components and/or dies on a substrate, such as a wafer, printed circuit board, fan out panel, die or the like. More particularly, the present invention relates to placement methods and systems where an alignment of the features of the placed device to the target has improved accuracy or precision.

### BACKGROUND

The state of the art solution for ultra-high accuracy placement is to create a heavy granite base to the machine, that is mounted on special vibration dampers to eliminate vibrations from outside the machine, caused by traffic in the vicinity of the machine. Also these machines do not have an integrated control system, to prevent fans from causing vibration, but have a separate cabinet for this purpose. On this heavy base the positioning system often is made of ceramic beams using air-bearings to provide completely smooth moves and no vibration.

There are multiple disadvantages to these type machines.

The first disadvantage is the cost. Typically these machines are very expensive compared to steel frame machines with steel beams, linear ball bearings and integrated control systems.

The second disadvantage is that these machines move the positioning systems slowly and need to allow for longer settle times to make sure that the placement nozzle has come to a complete stop. This is the reason these machines typically have lower output than less accurate equipment.

The third disadvantage is that these machines require a separate control cabinet which takes up extra floor space and is expensive in the clean rooms required for this type of assembly process.

Thus, an improved device, system and/or methodology for improving the accuracy of electronic assembly equipment to levels below 1 micron by eliminating the vibration of the nozzle of the placement head with respect to the substrate that the nozzle will be placing a device on would be well received in the art.

### SUMMARY

According to one aspect, an electronic assembly system that includes: a placement head including: a spindle; a positioning system configured to move the spindle between a picking location and a placement location; a spindle assembly Z-drive; a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller; and a spindle accelerometer system connected to the motion controller of the piezo stage, the spindle accelerometer system configured to measure vibrations in an X-direction and a Y-direction. The electronic assembly further includes a substrate support configured to hold a substrate that is a target for placement of an electronic component by the spindle; and a substrate accelerometer system mounted to the substrate support, the substrate accelerometer system configured to measure vibrations in the X-direction and the Y-direction, wherein the substrate accelerometer system is connected to the motion controller of the piezo stage.

According to another aspect, a placement head for an electronic assembly system comprises: a spindle; a positioning system configured to move the spindle between a picking location and a placement location; a spindle assembly Z-drive; a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller; and a spindle accelerometer system connected to the motion controller of the piezo stage, the spindle accelerometer system configured to measure vibrations in an X-direction and a Y-direction.

According to another aspect, a method for synchronizing a spindle head for vibration damping comprises: providing an electronic assembly system that includes: a placement head. The placement head includes: a spindle, a positioning system configured to move the spindle between a picking location and a placement location, a spindle assembly Z-drive; a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller, and a spindle accelerometer system connected to the motion controller of the piezo stage, the spindle accelerometer system configured to measure vibrations in an X-direction and a Y-direction. The electronic assembly system further includes a substrate support configured to hold a substrate that is a target for placement of an electronic component by the spindle, and a substrate accelerometer system mounted to the substrate support, the substrate accelerometer system configured to measure vibrations in the X-direction and the Y-direction, wherein the substrate accelerometer system is connected to the motion controller of the piezo stage. The method includes receiving, by the motion controller of the piezo stage, signals from the spindle accelerometer system, receiving, by the motion controller of the piezo stage, signals from the substrate accelerometer system. The method includes processing, by the motion controller of the piezo stage, the signals from each of the spindle accelerometer system and the substrate accelerometer system. The method includes synchronizing, by the motion controller of the piezo stage, relative vibrational motion between the placement head and a substrate attached to the substrates support caused by at least one vibration.

### BRIEF DESCRIPTION OF THE DRAWINGS

The above and further advantages of this invention may be better understood by referring to the following description in conjunction with the accompanying drawings, in which like reference numerals indicate like elements and features in the various figures. For clarity, not every element may be labeled in every figure. The drawings are not necessarily to scale, emphasis instead being placed upon illustrating the principles of the invention.

FIG. 1 depicts a top view of an electronic device placement system, according to one embodiment.

FIG. 2 depicts a side view of the electronic device placement system of FIG. 1, according to one embodiment.

FIG. 3A depicts a side schematic view of an electronic device placement system including a downward facing camera and a spindle having a nozzle picking up an electronic device moved out of a vision path of the downward facing camera, according to one embodiment.

FIG. 3B depicts a side schematic view of the electronic device placement system of FIG. 6A including the downward facing camera and having the nozzle picking up the electronic device over a substrate, according to one embodiment.

FIG. 4 depicts graphical representations of acceleration patterns over time caused by vibrations in the X and Y directions as measured by both spindle and substrate support accelerometer systems, before synchronized motion damping, in accordance with one embodiment.

FIG. 5 depicts graphical representations of acceleration patterns over time caused by vibrations in the X and Y directions as measured by both spindle and substrate support accelerometer systems, after synchronized motion damping, in accordance with one embodiment.

FIG. 6 depicts a method of placing an electronic device, according to one embodiment.

### DETAILED DESCRIPTION

Reference in the specification to “one embodiment” or “an embodiment” means that a particular feature, structure or characteristic described in connection with the embodiment is included in at least one embodiment of the teaching. References to a particular embodiment within the specification do not necessarily all refer to the same embodiment.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill having access to the teaching herein will recognize additional implementations, modifications and embodiments, as well as other fields of use, which are within the scope of the present disclosure as described herein.

The present disclosure enables placement of electronic devices, such as components, dies or the like, on a substrate or printed circuit board with an alignment of the features of device to the target on the substrate that is better than prior art equipment. For example, the present electronic device placements systems and methods described herein are capable of placing electronic devices with accuracies at or better than 1 micron.

Moreover, the embodiments described in this disclosure allow lower cost machines built with steel positioning systems and standard linear ball bearings to achieve the same, or better accuracies as the granite block machines with ceramic beams on air-bearings. It allows for much higher speeds, since even part of the settle-time can be eliminated, that makes state of the art high accuracy machines so slow. It may also save money on building construction by eliminating the need for separate control cabinets and damping floor materials, or routing any traffic inside building away from the state of the art machinery.

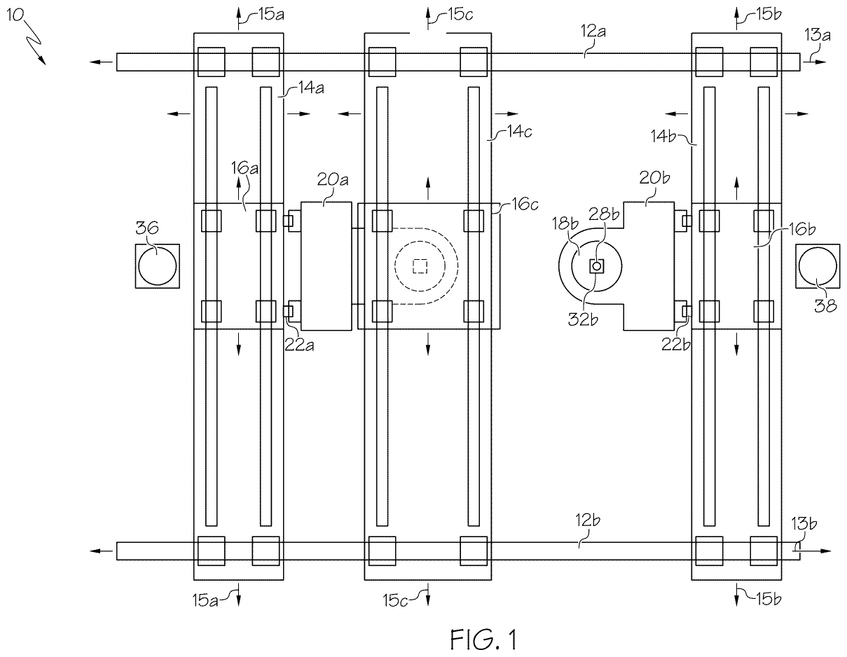

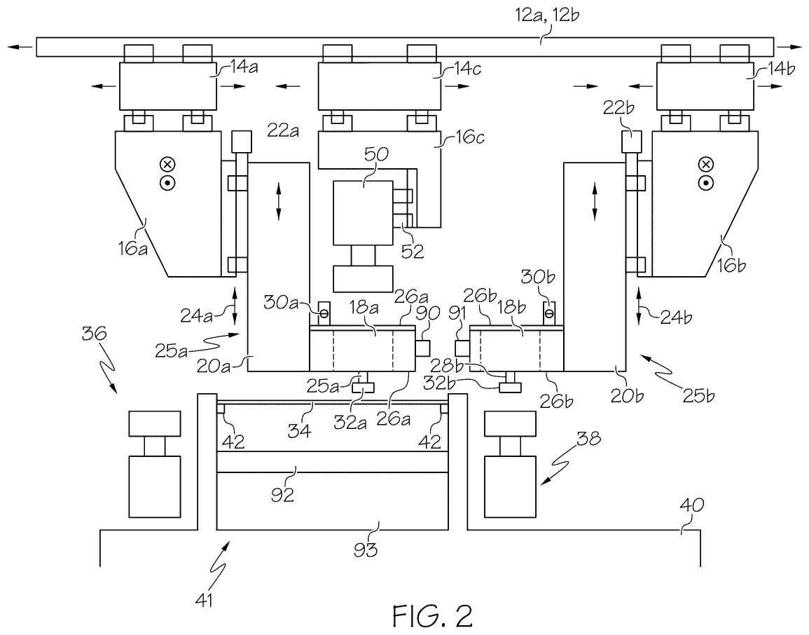

FIG. 1 depicts a top view of an electronic device placement system 10 while FIG. 2 depicts a side view of the electronic device placement system 10 of FIG. 1, according to one embodiment. As shown in FIGS. 1 and 2, the electronic device placement system 10 includes a positioning system that includes a pair of parallel linear bearings 12a, 12b disposed and extending in a Y-direction in Y-axes 13a, 13b, respectively. The positioning system further includes three beams extending between the pair of linear bearings 12a, 12b: a first beam 14a, a second beam 14b, and a third beam 14c.

The first beam 14a is movably coupled to the linear bearings 12a, 12b, and is disposed along a first X-axis 15a that is perpendicular to the Y-axes 13a, 13b. Likewise, the second beam 14b is movably coupled to the linear bearings 12a, 12b, and is disposed along a second X-axis 15b that is also perpendicular to the Y-axes 13a, 13b. Similarly, a third beam 14c is movably coupled to the linear bearings 12a, 12b and is disposed along a third X-axis 15c that is also perpendicular to the Y-axes 13a, 13b. Thus, the first, second and third beams 14a, 14b, 14c are parallel beams and disposed in a spaced apart manner along the Y-axes 13a, 13b between the pair of parallel linear bearings 12a, 12b. In particular, the third beam 14c is located between the first beam 14a and the second beam 14b. In other words, the first beam 14a is located on a first side of the electronic device placement system 10, while the second beam 14b is located on a second side of the electronic device placement system 10, with the third beam 14c located there between. The first, second and third beams 14a, 14b, 14c are each configured to independently move with respect to the linear bearings 12a, 12b in the Y-direction along the Y-axes 13a, 13b.

As shown, the positioning system includes a first carriage 16a that is movably coupled to the first beam 14a. The first carriage 16a is configured to move with respect to the first beam along the first X-axis 15a. Likewise, the positioning system further includes a second carriage 16b that is movably coupled to the second beam 14b. The second carriage 16a is configured to move with respect to the second beam 14b along the second X-axis 15b. Similarly, the positioning system includes a third carriage 16c that is movably coupled to the third beam 14c. The third carriage 16c is configured to move with respect to the third beam 14c along the third X-axis 15c.

The parallel linear bearings 12a, 12b and/or described beams 14a, 14b, 14c and/or the carriages 16a, 16b, 16c may include any type of positioning or bearing system configured to allow for movement of the spindle assemblies and/or downward facing camera system in both the X and Y directions along X and Y axes. The connection between these bearings, beams and carriages may take any form, such as wheels/rollers, sliding movement, or any other type of controllable precision bearing system.

A first spindle 18a of a first placement head 25a is movably coupled to the first carriage 16a. In particular, the first spindle 18a is attached or otherwise coupled to a first piezo stage 20a which is attached or coupled to a first spindle assembly Z-drive 22a. In particular, the first spindle assembly Z-drive 22a is movably coupled to the first carriage 16a and is configured to move with respect to the first carriage 16a along a first Z-axis 24a. The first spindle assembly Z-drive 22a is configured to move the first spindle 18a along the first Z-axis 24a. The first piezo stage 20a is movably coupled between the first spindle assembly Z-drive 22a and the first spindle 20a. The first piezo stage 20a is configured to move the first spindle 18a with respect to the first spindle assembly Z-drive 22a to make fine positioning adjustments to the positioning of the first spindle 18a.

Like the first spindle 18a, a second spindle 18b of a second placement head 25b is movably coupled to the second carriage 16b. In particular, the second spindle 18b is attached or otherwise coupled to a second piezo stage 20b which is attached or coupled to a second spindle assembly Z-drive 22b. In particular, the second spindle assembly Z-drive 22b is movably coupled to the second carriage 16b and is configured to move with respect to the second carriage 16b along a second Z-axis 24b. The second spindle assembly Z-drive 22b is configured to move the second spindle 18b along the second Z-axis 24b. The second piezo stage 20b is movably coupled between the second spindle assembly Z-drive 22b and the second spindle 20b. The second piezo stage 20b is configured to move the second spindle 18b with respect to the second spindle assembly Z-drive 22b to make fine positioning adjustments to the positioning of the second spindle 18b.

The first and second spindles 18a, 18b may be spindle assemblies which include a transparent first spindle body 19a, and a second transparent spindle body 19b, respectively. The transparent first and second spindle bodies 19a, 19b may each include a pair of glass plates 26a, 26b, one above and one below the structure of the spindles 18a, 18b. Instead of a glass plates, other transparent materials may be used especially if different wavelength light may be used for illumination, like infrared light or X-ray. Further, the primary structure of the spindles 18a, 18b may be made of transparent material. The first and second spindles 18a, 18b may include a vertically aligned nozzle 28a, 28b, respectively. The spindle nozzles 28a, 28b may be made of a transparent material as well in some embodiments. Still further, the first and second spindles 18a, 18b may each be configured to provide air distribution to the spindle nozzles 28a, 28b, respectively, in order to create a vacuum suction and/or air emission from the nozzles 28a, 28b. The spindles 18a, 18b may further contain a theta drive 30a, 30b, respectively, to rotate the glass plates enabling pick up and placement at different angles.

As shown, the nozzles 28a, 28b have each picked up a respective electronic device 32a, 32b, such as a component, die or the like. The combination of the positioning system of the linear bearings 12a, 12b, the beams 14a, 14b, and the Z-drives 22a, 22b, and the theta drives 30a, 30b enable the electronic device placement system 10 to pick up an electronic device 32a, 32b, and move the electronic device 32a, 32b during all the large distances by the positioning system in the X, Y, Z axes and the theta (rotational) axis. Once the first and second spindles 18a, 18b, with a picked electronic device 32a, 32b attached or otherwise on the nozzles 28a, 28b, the electronic devices 32a, 32b may be transported from a picking location, such as a feeder area and/or feeder bank (not shown), to a device imaging location and/or a placement location over a substrate 34 or other target, as described herein below.

In the embodiment shown, the electronic device placement system 10 further includes a first upward facing camera 36 facing upward that is configured to image a bottom of an electronic device. In particular, the first upward facing camera 36 may be configured to image an electronic device picked up by the first spindle 18a, such as the first electronic device 32a. The imaging of the first upward facing camera 36 occurs prior to the placement stroke of the first spindle 18a for placing the first electronic device 32a.

Like the first upward facing camera 36, the electronic device placement system 10 further includes a second upward facing camera 38 facing upward and configured to image a bottom an electronic device. In particular, the second upward facing camera 38 may be configured to image an electronic device picked up by the second spindle 18b, such as the second electronic device 32b. The imaging of the second upward facing camera 38 occurs prior to the placement stroke of the second spindle 18b for placing the second electronic device 32b.

The electronic device placement system 10 further includes a machine base 40 located under the positioning system, the linear bearings 12a, 12b, the beams 14a, 14b, 14c and the like. The positioning system may be operably attached or connected to the machine base 40 of the electronic device placement system 10. The machine base 40 includes substrate support 41 having a substrate holder system 42 for holding the substrate 34, upon which the first and second electronic devices 32a, 32b are placeable during a placement stroke of the respective first and second spindles 18a, 18b. The first upward facing camera 36 facing upward is located on a first side of the substrate holder system 42 and the second upward facing camera 38 facing upward is located on a second side of the substrate holder 42. In other words, the first side of the substrate holder 42 is proximate a first end of the linear bearing(s) 12a, 12b, and the second side of the substrate holder 42 is proximate a second (opposite) end of the linear bearings 12a, 12b.

The electronic device placement system 10 further includes a downward facing camera 50 coupled to the third carriage 16c. While the embodiment shown in FIGS. 1 and 2 includes a single downward facing camera 50, it should be understood that embodiments are contemplated where more than one downward facing camera are deployed. For example, a downward facing camera may be deployed for each individual placement head and/or spindle assembly. As shown in FIGS. 1-2, the downward facing camera 50 is movable above the first spindle 18a during placement of a first electronic device by the first spindle 18a, such as the first electronic device 32a. The downward facing camera 50 may be positionable roughly located over the target (e.g., within 100 micron) in the X, Y, Z axes and the rotational axis, and the large axes X, Y and Z and theta of the positioning system of the beams 14a, 14b, 14c, carriages, 16a, 16b, 16c, and Z-Drives 22a, 22b, 52 come to a complete stop.

Once in position, the downward facing camera 50 is configured to image outer edges of picked electronic devices during a placement stroke of the first spindle 18a through the transparent first spindle body (as described above). Likewise, the downward facing camera 50 is movable above the second spindle 18b during placement of a second electronic device by the second spindle 18b, such as the second device 32b. In order for this to occur, the first beam 14a may be moved along the linear bearings 12a, 12b away from the substrate 34 and toward the upward facing camera 36 and/or a feeder bank or picking location. Then, the second beam 14b may be moved above or over the substrate 34. Here, the downward facing camera 50 may thereby be configured to image outer edges of picked electronic devices during a placement stroke of the second spindle 18b through the transparent second spindle body (as described above). The downward facing camera 50 is also capable of, or configured to, being moved in the vertical Z-direction, via a camera Z-drive 52 to enable focusing on the substrate 34, but also on the device when the downward facing camera 50 is suspended above the substrate 34.

Thus, the first and second beams 14a, 14b (i.e. placement beams) of the system 10 carries the spindles 18a, 18b, respectively, and can move each spindle 18a, 18b independent of the third beam 14c (i.e. the camera beam) in the X, Y, and Z axes as long as the first and second beams 14a, 14b stay on respective sides of the third beam 14c. In other words, the first, second and third beams 14a, 14b, 14c may not be capable of passing each other in the Y-direction along the linear bearings 12a, 12b.

In order to provide room for the downward facing camera 50, the spindle assemblies may be extended from the respective placement head-beam (i.e. the first and second beams 14a, 14b) in the direction of the camera beam (i.e. the third beam 14c) such that it can position the spindles 18a, 18b underneath the downward facing camera 50, when the beams get close to each other. For example, the first spindle 18a is positionable directly under the downward facing camera 50 when the first beam 14a is proximate the third beam 14c, and the second spindle 18b is positionable directly under the downward facing camera 50 when the second beam 14b is proximate the third beam 14c.

The extended part of each of the spindles 18a, 18b carries the nozzle 28a, 28b mounted vertically between the centers of the two horizontal glass plates 18a, 18b to allow the downward facing camera 50 on the third beam 14c to be positioned above the glass plates to image the outer edges of a picked device during the actual placement stroke and actively align this edge with the target on the substrate 34.

The first and second piezo stages 20a, 20b may be each configured to make fine adjustments to the positioning of the first and second spindles 18a, 18b, respectively, in 6 axial directions, including an X-axial direction, a Y-axial direction, a Z-axial direction, a theta rotational axial direction, an alpha rotational axial direction, and a beta rotational axial direction. The X-axial direction may be parallel to the X-axes 15a, 15b, 15c, the Y-axial direction may be parallel to the Y-axes 13a, 13b, and the Z-axial direction may be parallel to the Z-axes 24a, 24b. The alpha rotational direction may be a rotation which is about an axis that is parallel to the X-axes 15a, 15b, 15c, the beta rotational direction may be a rotation which is about an axis that is parallel to the Y-axes 13a, 13b, and the theta rotational direction may be a rotation which is about an axis that is parallel to the Z-axes 24a, 24b.

For the final adjustments the 6 degree of freedom Piezo actuator driven stage is mounted between the PH-beam carriage's Z-drive and the placement head and/or spindle assembly and is able to make precision position adjustments based on the spindle-camera information of the difference between target position and actual position of the device, while moving in small steps slowly to the substrate. The piezo stages described herein are capable of making sub-micron adjustments of the device on the nozzle tip with respect to the spindle-camera and the substrate in the X, Y, and Z directions, but also in theta, alpha and beta angles. The angular adjustments are needed for theta to be more accurate than the traditional theta servo drive. The adjustment for alpha and beta enables an improved coplanar touchdown of the device on the substrate, preventing crushing of corner interconnect features on the device or the substrate.

The piezo stages 20a, 20b of the placement heads 25a, 25b may each include a respective motion controller housed within the body of the piezo stages 20a, 20b. The motion controllers may each be a computer system or processor located within the piezo stage including the ability to receive and process signals from motion sensors within the electronic device placement system 10. The motion controller may include a processor, at least one memory device, and/or at least one data storage system, for example. The motion controller may include a signal receiver, which may be wired or wireless in various embodiments.

In particular, the motion controllers may each be connected to respective spindle accelerometer systems 90, 91, which are attached to the spindles 18a, 18b of the respective placement heads 25a, 25b. The spindle accelerometer systems 90, 91 may each be configured to measure vibrations in the respective spindles 18a, 18b and/or the nozzles 28a, 28b thereof in both an X-direction and a Y-direction. These measurements may be provided to the respective motion controller of the piezo stage 20a, 20b in real time for processing.

Additionally, a substrate accelerometer system 92 may be mounted to the substrate support 41. The substrate accelerometer system 92 may be proximate a transducer 93 and may be configured to measure vibrations in the substrate support 41 in both the X-direction and the Y-direction. Like the spindle accelerometer systems 90, 91, the substrate accelerometer system 92 may also be communicatively connected to the motion controller of each of the piezo stages 20a, 20b.

Each of the spindle accelerometer systems 90, 91 may include one or more accelerometers. For example, the spindle accelerometer systems 90, 91 may include a first accelerometer device configured to measure vibrations of the respective spindles 18a, 18b in the X-direction and a second accelerometer device configured to measure vibrations of the respective spindles 18a, 18b in the Y-direction. Thus, these sets of respective accelerometers for each of the X- and Y-direction may be rigidly mounted near the respective spindles 18a, 18b and/or nozzles 28a, 28b to measure vibrations of the respective spindles 18a, 18b and/or nozzles 28a, 28b.

Similarly, the substrate accelerometer system 92 may include a first accelerometer device configured to measure vibrations in the substrate support in the X-direction and a second accelerometer device configured to measure vibrations in the substrate support in the Y-direction. Thus, this set of accelerometers may be mounted rigidly to the substrate support 41 that holds the substrate 34 to measure vibrations of the substrate 34.

Utilizing the signals and received information provided by the accelerometer systems 90, 91, 92, the motion controller of the piezo stages 20a, 20b may each be configured to eliminate relative motion between the spindle and the substrate support. Moreover, the motion controller of the piezo stages 20a, 20b may each be configured to account for beam vibrations, control system fan vibrations, and outside system vibrations. The motion controller may be configured to operate the piezo stage 20a, 20b of each of the placement heads 25a, 25b to adjust the movement of the nozzle to correspond to the movement of the substrate support 41 to reduce relative motion between these two structures. Processing both sets of signals (signals from the spindle accelerometer system and the substrate accelerometer system) allows for the piezo stage 20a, 20b to vibrate the nozzle 28a, 28b in the exact same direction with the same magnitude as the vibration of the substrate 34. This eliminates the relative movement between the device 32a, 32b on the nozzle tip and the substrate 34 enabling sub-micron placement.

As described above, in exemplary embodiments herein, the electronic device placement systems and methods utilize one or more Cartesian positioning system beams in an electronic device placement assembly machine or system. The beams disclosed herein are configured to move along the same linear bearings in a Y-direction, and enable carriages to move along each beam in the X-direction. The camera beam carries the spindle-camera looking down vertically. This camera can image the substrate and, using a vision system, can determine position of the interconnect features on the substrate, which is the target for the device to be placed. The cartesian positioning systems described herein may be constructed with steel, or a similar robust metallic material and may further include standard linear ball bearings.

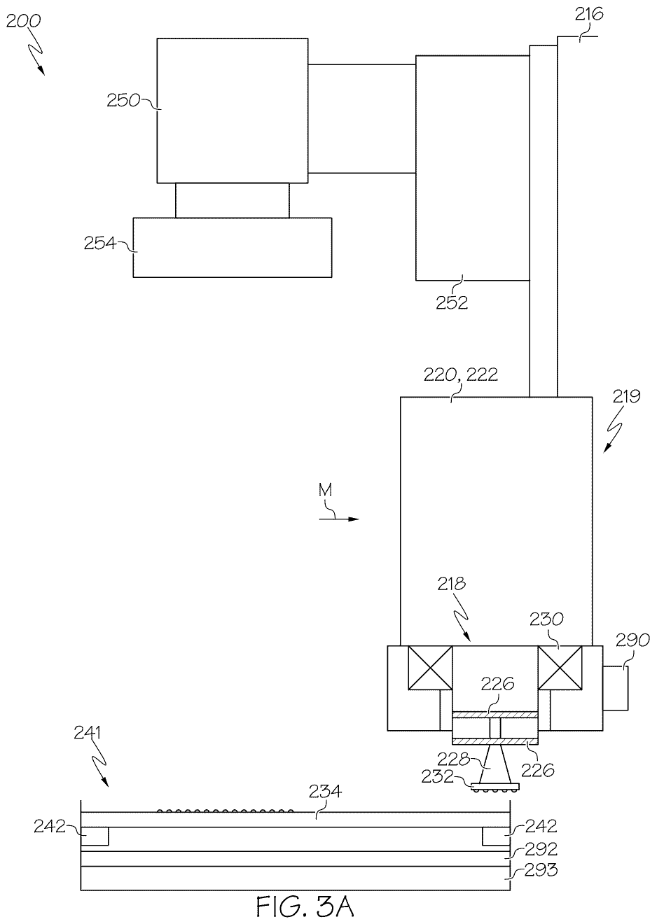

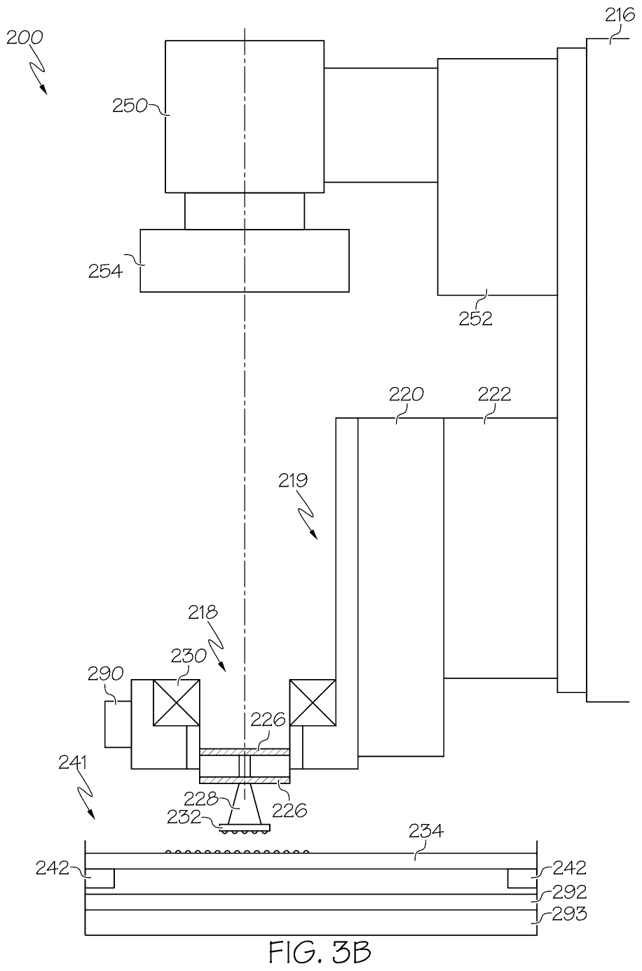

FIG. 3A depicts a side schematic view of an electronic device placement system 200 including a downward facing camera 250 and a spindle 218 of a placement head 219 having a nozzle 228 picking up an electronic device 228 moved out of a vision path of the downward facing camera 250, according to one embodiment. FIG. 3B depicts a side schematic view of the electronic device placement system 200 including the downward facing camera 250 and having the nozzle 228 picking up the electronic device 228 over a substrate 234, according to one embodiment.

While not shown, the electronic device placement system 200 may include a positioning system having a pair of linear bearings, such as the linear bearings 12a, 12b, and at least one beam, such as one of the beams 14a, 14b, 14c. Upon this beam, a carriage 216 is shown, upon which both the downward facing camera 250 and the spindle 218 is movably coupled. Thus, the beam in this embodiment may movably coupled to the at least one bearing disposed along an X-axis that is perpendicular to the Y-axis. The beam may be configured to move with respect to the at least one linear bearing along the Y-axis to effectuate X and Y directional movement. The carriage 216 may be movably coupled to the beam and may be configured to move with respect to the beam along the X-axis.

The electronic device placement system 200 includes a spindle assembly Z-drive 222 movably coupled to the carriage 216 that is configured to move with respect to the carriage along a Z-axis that is vertical and perpendicular to each of the X-axis and the Y-axis. Similarly, a spindle 218 is coupled to the spindle assembly Z-drive 222. The spindle may be the same or similar to the spindles 18a, 18b described hereinabove. As shown, the spindle 218 includes a nozzle 228 mounted vertically to a transparent spindle body. The transparent spindle body includes two glass plates 226. As shown, the spindle 218 includes a theta drive 230 to rotate the spindle 218 and the nozzle 228.

While not shown, the electronic device placement system 200 may include a camera facing upward and configured to image a bottom of an electronic device 232, like one of the upward facing cameras 36, 38 described hereinabove. The electronic device placement system 200 may only include a single upward facing camera in this single spindle embodiment. The device camera may be configured to image the electronic device 232 picked up by the nozzle 228 of the spindle 218 prior to a placement stroke of the electronic device 232.

The electronic device placement system 200 includes a downward facing camera 250 movable above the spindle 218 during placement of the electronic device 232 by the spindle 218, as shown in FIG. 3B. The downward facing camera 250 is configured to image outer edges of the electronic device 232 during the placement stroke of the spindle 218 through the transparent spindle body. The downward facing camera 250 may include a lens and/or lighting system 254 to facilitate proper imaging. The downward facing camera 250 may include a camera Z-drive 252 movably coupled to the carriage 216 configured to move with respect to the carriage in the Z-axis. Thus, the downward facing camera 250 and the spindle 218 may be movably coupled to the same carriage 216 in the embodiment shown. However, the downward facing camera 250 may be independently movable with respect to the carriage 216 in the Z-axis from the spindle 218. Thus, each of the spindle 218 and the downward facing camera 250 include dedicated individual Z-drives 222, 252 for independent motion.

As shown in FIG. 3A, the spindle 218 may be configured to move out from a vision path of the downward facing camera 250 along a movement path M when the spindle camera is pointed at a placement location. In the embodiment shown, the spindle 218 may be configured to hingedly rotatably about the carriage 216. However, in other embodiments, the spindle 218 may be movable along a spindle linear bearing (not shown) with respect to the carriage 216 to move out from below the downward facing camera 250 and allow for direct imaging by the downward facing camera 250 of the substrate 234. The spindle 218 may be movable with respect to the downward facing camera 250 by at least one degree of freedom. Alternatively, spindle 218 may be movable with respect to the downward facing camera 250 by at least two degrees of freedom (i.e., vertical independent motion, and horizontal independent motion).

Further, while not shown, the electronic device placement system 200 includes a machine frame and substrate holder system, similar to the machine frame 40, the substrate support 41 and the substrate holder system 42 described herein above. In particular, the electronic device placement system 200 includes a substrate support 241 having a substrate holder system 242 for holding the substrate 234.

The electronic device placement system 200 further includes a piezo stage 220 movably coupled between the spindle assembly Z-drive 222 and the spindle 218. The piezo stage 220 may be configured to move the spindle 218 with respect to the spindle assembly Z-drive 222 to make fine positioning adjustments to the positioning of the spindle 218. The piezo stage is configured to make fine adjustments to the positioning of the spindle in 6 axial directions, including an X-axial direction, a Y-axial direction, a Z-axial direction, a theta rotational axial direction, an alpha rotational axial direction, and a beta rotational axial direction, similar to the piezo stages 20a, 20b described herein above.

The piezo stage 220 of the placement head 219 may include a motion controller housed within the body of the piezo stage 219. The motion controller may be a computer system or processor located within the piezo stage 219 including the ability to receive and process signals from motion sensors within the electronic device placement system 200. The motion controller may include a processor, at least one memory device, and/or at least one data storage system, for example. The motion controller may further include a signal receiver, which may be wired or wireless in various embodiments.

In particular, the motion controller may be connected to a spindle accelerometer system 290, attached to the placement head 219 and the spindle 218 thereof. The spindle accelerometer system 290 may be configured to measure vibrations in the spindle 218 and/or nozzle 228 thereof in both an X-direction and a Y-direction. These measurements may be provided to the motion controller of the piezo stage 220 in real time for processing.

Additionally, a substrate accelerometer system 292 may be mounted to the substrate support 241. The substrate accelerometer system 292 may be proximate a transducer 293 and may be configured to measure vibrations in the substrate support 241 in both the X-direction and the Y-direction. Like the spindle accelerometer system 290, the substrate accelerometer system 292 may also be communicatively connected to the motion controller of the piezo stage 220.

The spindle accelerometer system 290 may include one or more accelerometers. For example, the spindle accelerometer system 290 may include a first accelerometer device configured to measure vibrations of the spindle 218 in the X-direction and a second accelerometer device configured to measure vibrations of the spindle 218 in the Y-direction. Thus, these sets of respective accelerometers for each of the X- and Y-direction may be rigidly mounted near the spindle 218 and/or nozzle 228 of the placement head 200 to measure vibrations of the spindle 218 and/or nozzle 228.

Similarly, the substrate accelerometer system 292 may include a first accelerometer device configured to measure vibrations in the substrate support in the X-direction and a second accelerometer device configured to measure vibrations in the substrate support in the Y-direction. Thus, this set of accelerometers may be mounted rigidly to the substrate support 241 that holds the substrate 234 to measure vibrations of the substrate 234.

Utilizing the signals and received information provided by the accelerometer systems 290, 292, the motion controller of the piezo stage 220 may be configured to eliminate relative motion between the spindle and the substrate support. Moreover, the motion controller of the piezo stage 220 may be configured to account for beam vibrations, control system fan vibrations, and outside system vibrations. The motion controller may be configured to operate the piezo stage 220 of the placement heads 219 to adjust the movement of the nozzle 228 and/or spindle 218 to correspond to the movement of the substrate support 241 and/or substrate 243 to reduce relative motion between these two structures. Processing both sets of signals (signals from the spindle accelerometer system and the substrate accelerometer system) allows for the piezo stage 220 to vibrate the nozzle 228 in the exact same direction with the same magnitude as the vibration of the substrate 234. This eliminates the relative movement between the device 232 on the nozzle tip and the substrate 234 enabling sub-micron placement.

As described above, in exemplary embodiments herein, the electronic device placement systems and methods utilize one or more Cartesian positioning system beams in an electronic device placement assembly machine or system. The beams disclosed herein are configured to move along the same linear bearings in a Y-direction, and enable carriages to move along each beam in the X-direction. The camera beam carries the spindle-camera looking down vertically. This camera can image the substrate and, using a vision system, can determine position of the interconnect features on the substrate, which is the target for the device to be placed. The cartesian positioning systems described herein may be constructed with steel, or a similar robust metallic material and may further include standard linear ball bearings.

In the various embodiments described above, the sequence of events may be as follows. First, the positioning system may make all the large-scale moves in X-, Y- and Theta. When the positioning system moves the placement head and spindle assembly and/or nozzle thereof into position to place the part, the beam and the placement head and the spindle assembly with the nozzle may still be vibrating. Likewise, the substrate held down on the substrate support may also be likely to vibrate, because of beam vibrations, control system fans' vibration, or vibrations from outside like traffic in the vicinity of the machine. The accelerometers within the system at the placement head and within the substrate holder will detect all these source of vibration at all the different frequencies, independent of what the source for these vibrations is. The motion controller or control system for the piezo stage provides near instant motion that may be capable of eliminating almost all relative motion by moving the nozzle in synch with the substrate. This allows alignment of the device on the nozzle tip with the target on the substrate.

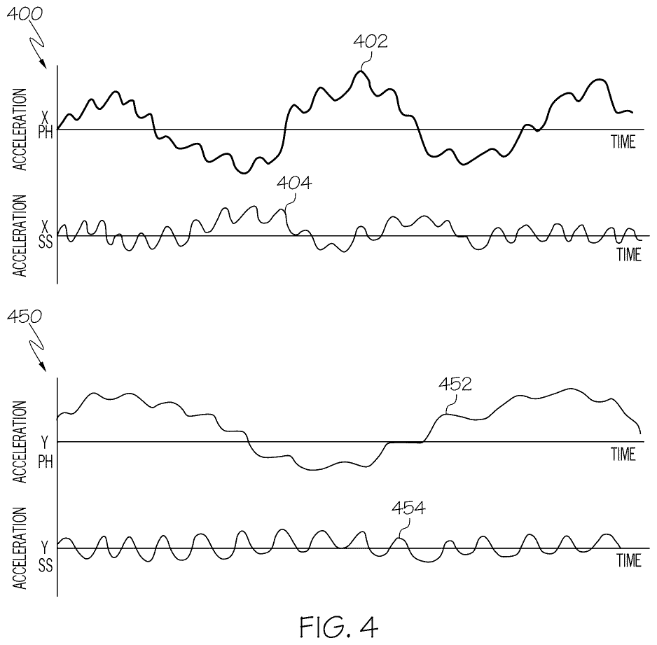

FIG. 4 depicts graphical representations of acceleration patterns over time caused by vibrations in the X and Y directions as measured by both spindle and substrate support accelerometer systems, before synchronized motion damping, in accordance with one embodiment. In particular, graph 400 includes a first acceleration pattern 402 over time of a spindle of the placement head in the X-direction. The graph 400 further includes a second acceleration pattern 404 over time of a substrate in the X-direction. Further, graph 450 includes a third acceleration pattern 452 over time of a spindle of a placement head in the Y-direction. The graph 450 further includes a second acceleration pattern 454 over time of the substrate in the Y-direction. As described hereinabove, the various patterns 402, 404, 452, 454 are provided prior to synchronized motion control and damping. The various patterns 402, 404, 452, 454 may be representations of data acquired by the motion controller of the piezo stage of a placement head from the accelerometer systems of the placement head and substrate support, as described hereinabove, before the piezo stage applies the synchronized motion control and damping in accordance to embodiments described herein.

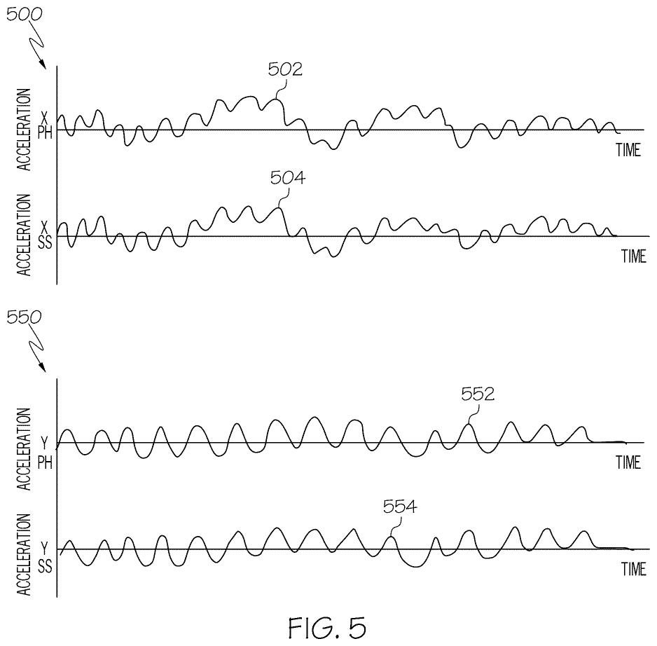

FIG. 5 depicts graphical representations of acceleration patterns over time caused by vibrations in the X and Y directions as measured by both spindle and substrate support accelerometer systems, after synchronized motion damping, in accordance with one embodiment. In particular, graph 500 includes a first acceleration pattern 502 over time of a placement head in the X-direction. The graph 500 further includes a second acceleration pattern 504 over time of a substrate in the X-direction. Further, graph 550 includes a third acceleration pattern 552 over time of a spindle of a placement head in the Y-direction. The graph 550 further includes a second acceleration pattern 554 over time of the substrate in the Y-direction. As described hereinabove, the various patterns 502, 504, 552, 554 are provided after synchronized motion control and damping. The various patterns 502, 504, 552, 554 may be representations of data acquired by the motion controller of the piezo stage of a placement head from the accelerometer systems of the sspindle and substrate support, as described hereinabove, after the piezo stage applies the synchronized motion control and damping in accordance to embodiments described herein.

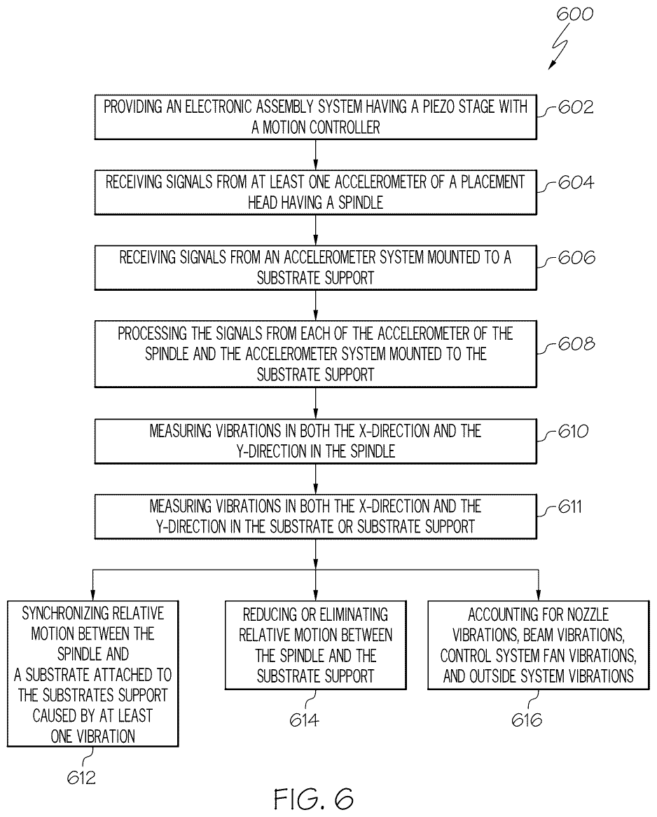

FIG. 6 depicts a method 600 of placing an electronic device, such as the electronic devices 32a, 32b, 232, according to one embodiment. The method 600 includes a first step 602 of providing an electronic assembly system, such as one of the electronic assembly systems 10, 200, having a piezo stage, such as one of the piezo stages 20a, 20b, 200, where the piezo stage includes a motion controller. The method 600 includes a step 604 of receiving signals from at least one accelerometer or accelerometer system, such as the accelerometer system 90, 91, 290, attached to a spindle, such as one of the spindles 18a, 18b, 218, of a placement head, such as the placement head 25a, 25b, 219.

The method 600 may include various steps which are performable by a motion controller of the piezo stage of the placement head. For example, the method 600 includes a step 606 of receiving signals from an accelerometer system, such as one of the accelerometer systems 92, 292, mounted to a substrate support, such as one of the substrate supports 41, 241. The method 600 includes a step 608 of processing the signals from the accelerometer system of the spindle and the accelerometer system mounted to the substrate support. The step 608 may be performable by a motion controller system located within the piezo stage of the placement head. The method 600 may include a step 610 of measuring vibrations in both the X-direction and the Y-direction of the spindle. The step 610 may further be performable by the motion controller of the piezo stage of the placement head. The method 600 may further include a step 611 of measuring vibrations in both the X-direction and the Y-direction of the substrate support.

The method 600 may include a step 612 of synchronizing relative motion between the spindle and a substrate attached to the substrates support caused by at least one vibration. The step 612 may be performable by the motion controller of the piezo stage of the placement head. The method 600 may include a step 614 of reducing or eliminating relative motion between the spindle and the substrate support. The step 614 may be performable by the motion controller of the piezo stage of the placement head. The method 600 may further include a step 616 of accounting for nozzle vibrations, beam vibrations, control system fan vibrations, and outside system vibrations. The step 614 may be performable by the motion controller of the piezo stage of the placement head.

The methods described herein may provide for placing the electronic device picked up by the nozzle of the spindle assemblies described with accuracy better than 1 micron. The embodiments described in this disclosure allow lower cost machines built with steel positioning systems and standard linear ball bearings to achieve the same, or better accuracies as the granite block machines with ceramic beams on air-bearings. Embodiments described herein allow for higher speeds. This is because the embodiments described herein reduce or eliminate settle-time, which is what makes state of the art high accuracy machines so slow. Embodiments described herein may further save money on building construction by eliminating the need for separate control cabinets and damping floor materials, or routing any traffic inside building away from the state of the art machinery. Various other advantages may be achieved through application of the concepts provided herein.

While the above embodiment is exemplary, in various other embodiments, it is contemplated that multiple spindle assemblies or spindles may be mounted on single Piezo Stage. Further, while the accelerometer systems described hereinabove describe measuring and accounting for acceleration in both the X and Y direction, these two directions may be exemplary. For example, transducers with accelerometers and rate gyroscopes may be used to compensate and synchronize motion for any or all of X-, Y-, Z-, Alpha, Beta and Theta vibrations, where X and Y are the horizontal axes, Z is the vertical axis, and alpha, beta and theta are rotational axis.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. An electronic assembly system comprising:
a placement head including:
a spindle;
a positioning system configured to move the spindle between a picking location and a placement location;
a spindle assembly Z-drive;
a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller; and
a spindle accelerometer system connected to the motion controller of the piezo stage, the spindle accelerometer system configured to measure vibrations in an X-direction and a Y-direction;
a substrate support configured to hold a substrate that is a target for placement of an electronic component by the spindle; and
a substrate accelerometer system mounted to the substrate support, the substrate accelerometer system configured to measure vibrations in the X-direction and the Y-direction, wherein the substrate accelerometer system is connected to the motion controller of the piezo stage.

2. The electronic assembly system of claim 1, wherein the spindle accelerometer system includes a first accelerometer configured to measure vibrations of the spindle in the X-direction and a second accelerometer configured to measure vibrations of the spindle in the Y-direction.

3. The electronic assembly system of claim 2, wherein the substrate accelerometer system includes a first accelerometer configured to measure vibrations in the substrate support in the X-direction and a second accelerometer configured to measure vibrations in the substrate support in the Y-direction.

4. The electronic assembly system of claim 1, wherein the piezo stage is configured to make fine adjustments to a positioning of the spindle in 6 axial directions, including an X-axial direction, a Y-axial direction, a Z-axial direction, a theta rotational axial direction, an alpha rotational axial direction, and a beta rotational axial direction.

5. The electronic assembly system of claim 4, wherein the motion controller of the piezo stage is configured to process signals from each of the spindle and substrate accelerometer systems.

6. The electronic assembly system of claim 5, wherein the motion controller is configured to eliminate relative vibrational motion between the spindle and the substrate support.

7. The electronic assembly system of claim 6, wherein the motion controller of the piezo stage is configured to account for beam vibrations, control system fan vibrations, and outside system vibrations.

8. The electronic assembly system of claim 1, wherein the positioning system is made of steel and uses linear ball bearings.

9. A placement head for an electronic assembly system comprising:
a spindle;
a positioning system configured to move the spindle between a picking location and a placement location;
a spindle assembly Z-drive;
a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller; and
a spindle accelerometer system connected to the motion controller of the piezo stage, the spindle accelerometer system configured to measure vibrations in an X-direction and a Y-direction.

10. The placement head of claim 9, wherein the spindle accelerometer system includes a first accelerometer configured to measure vibrations of the spindle in the X-direction and a second accelerometer configured to measure vibrations of the spindle in the Y-direction.

11. The placement head of claim 9, wherein the piezo stage is configured to make fine adjustments to a positioning of the spindle in 6 axial directions, including an X-axial direction, a Y-axial direction, a Z-axial direction, a theta rotational axial direction, an alpha rotational axial direction, and a beta rotational axial direction.

12. The placement head of claim 11, wherein the motion controller of the piezo stage is connectable to a substrate accelerometer system mounted to a substrate support of the electronic assembly system.

13. The placement head of claim 12, wherein the motion controller of the piezo stage is configured to process signals from each of the spindle and substrate accelerometer systems.

14. The placement head of claim 13, wherein the motion controller of the piezo stage is configured to reduce or eliminate relative vibrational motion between the spindle and the substrate support.

15. The placement head of claim 14, wherein the motion controller of the piezo stage is configured to account for nozzle vibrations, beam vibrations, control system fan vibrations, and outside system vibrations.

16. A method for synchronizing a spindle head for vibration damping comprising:
providing an electronic assembly system that includes:
a placement head including:
a spindle;
a positioning system configured to move the spindle between a picking location and a placement location;
a spindle assembly Z-drive;
a piezo stage movably coupled between the spindle assembly Z-drive and the spindle, the piezo stage configured to move the spindle with respect to the spindle assembly Z-drive to make fine positioning adjustments to the positioning of the spindle, the piezo stage including a motion controller; and
a spindle accelerometer system connected to the motion controller of the piezo stage, the spindle accelerometer system configured to measure vibrations in an X-direction and a Y-direction;
a substrate support configured to hold a substrate that is a target for placement of an electronic component by the spindle; and
a substrate accelerometer system mounted to the substrate support, the substrate accelerometer system configured to measure vibrations in the X-direction and the Y-direction, wherein the substrate accelerometer system is connected to the motion controller of the piezo stage;
receiving, by the motion controller of the piezo stage, signals from the spindle accelerometer system;
receiving, by the motion controller of the piezo stage, signals from the substrate accelerometer system;
processing, by the motion controller of the piezo stage, the signals from each of the spindle accelerometer system and the substrate accelerometer system; and
synchronizing, by the motion controller of the piezo stage, relative vibrational motion between the spindle and a substrate attached to the substrates support caused by at least one vibration.

17. The method of claim 16, further comprising measuring vibrations in both the X-direction and the Y-direction of the spindle.

18. The method of claim 16, further comprising receiving, by the motion controller of the piezo stage, signals from each of a first and a second accelerometer of the spindle accelerometer system.

19. The method of claim 16, further comprising reducing or eliminating, by the motion controller of the piezo stage, relative motion between the spindle and the substrate support.

20. The method of claim 17, further comprising accounting for, by the motion controller of the piezo stage, nozzle vibrations, beam vibrations, control system fan vibrations, and outside system vibrations.
